(19) United States
(12) Patent Application Publication
(10) Pub. No.: US 2025/0221122 A1
(43) Pub. Date: Jul. 3, 2025

(54) LIGHT-EMITTING DEVICE AND METHOD FOR MANUFACTURING LIGHT-EMITTING DEVICE

(71) Applicant: STANLEY ELECTRIC CO., LTD., Meguro-ku, Tokyo (JP)

(72) Inventor: Momo EDAMURA, Tokyo (JP)

(73) Assignee: STANLEY ELECTRIC CO., LTD., Meguro-ku, Tokyo (JP)

(21) Appl. No.: 18/847,738

(22) PCT Filed: Mar. 8, 2023
(86) PCT No.: PCT/JP2023/008734

§ 371 Date: Sep. 17, 2024

(30) Foreign Application Priority Data
Mar. 22, 2022 (JP) 2022-045486

(51) Int. Cl. H10H 20/80; H10H 20/832; H10H 20/851; H10H 29/24

(52) U.S. Cl. CPC H10H 20/882; H10H 20/835; H10H 20/8512; H10H 29/24

(57) ABSTRACT

A light-emitting device of the present invention includes a plate-shaped substrate, a light-emitting element, a wavelength converter, and a light scattering material. The light-emitting element includes a semiconductor structure layer and a translucent substrate. The semiconductor structure layer is disposed on one main surface of the substrate and includes a light-emitting layer. The translucent substrate is disposed on the semiconductor structure layer and has a plate shape and a translucency. The wavelength converter contains phosphor particles and disposed on an upper surface of the translucent substrate via an adhesive resin. The light scattering material is made of a resin material containing light scattering particles. The light scattering material is formed so as to cover from a side surface of the wavelength converter to a side surface of the light-emitting element and the one main surface of the substrate. The light scattering material includes: a first inclined surface inclined outwardly downward from an upper end of the side surface of the wavelength converter; a flat surface formed continuously with the first inclined surface and extending along the one main surface; and a second inclined surface formed continuously with an outer end of the flat surface and inclined outwardly upward. A height position of the flat surface from the one main surface of the substrate is lower than a lower surface of the wavelength converter.

### TECHNICAL FIELD

The present invention relates to a light-emitting device including a semiconductor light-emitting element and a method for manufacturing the same.

### BACKGROUND ART

Conventionally, there has been known light-emitting devices that include a substrate, a light-emitting element having a semiconductor light-emitting layer mounted on the substrate, a wavelength converter that converts the wavelength of light emitted from the light-emitting element, and a light reflector that seals a portion excluding a light-exiting surface of the wavelength converter and reflects light from the light-emitting element and the wavelength converter.

For example, Patent Document 1 discloses a light-emitting device including a substrate, a light-emitting element mounted on the substrate, a light-transmitting member including a phosphor as a wavelength conversion material, and a covering member containing a light reflective material and covering side surfaces of the light-emitting element and the light-transmitting member.
Patent Document 1: JP-A-2010-219324

### DISCLOSURE OF THE INVENTION

### Problems to be Solved by the Invention

In the light-emitting device disclosed in Patent Document 1, the object is to reflect light from the light-emitting element and the light-transmitting member with the covering member containing the light reflective material and emit light only from the light-exiting surface of the light-transmitting member.

However, a problem with the light-emitting device disclosed in Patent Document 1 is that light that enters the covering member is attenuated by multiple reflections or the like in the covering member, thus reducing a light extraction efficiency of the light-emitting device.

The present invention has been made in consideration of the above-described point and an object of which is to provide a light-emitting device capable of avoiding a decrease in total luminous flux of light emitted from the light-emitting device and improving the light extraction efficiency, and a method for manufacturing the light-emitting device.

### Solutions to the Problems

A light-emitting device according to the present invention includes a plate-shaped substrate, a light-emitting element, a wavelength converter, and a light scattering part. The light-emitting element includes a semiconductor structure layer and a translucent substrate. The semiconductor structure layer is disposed on one main surface of the substrate and includes a light-emitting layer. The translucent substrate is disposed on the semiconductor structure layer and has a plate shape and a translucency. The wavelength converter contains phosphor particles and disposed on an upper surface of the translucent substrate via an adhesive resin. The light scattering part is made of a resin material containing light scattering particles. The light scattering part is formed so as to cover from a side surface of the wavelength converter to a side surface of the light-emitting element and the one main surface of the substrate. The light scattering part includes a first inclined surface inclined outwardly downward from an upper end of the side surface of the wavelength converter; a flat surface formed continuously with the first inclined surface and extending along the one main surface; and a second inclined surface formed continuously with an outer end of the flat surface and inclined outwardly upward. A height position of the flat surface from the one main surface of the substrate is lower than a lower surface of the wavelength converter.

A method for manufacturing a light-emitting device according to the present invention includes: an element bonding step of bonding a light-emitting element onto one main surface of the substrate, the light-emitting element including a semiconductor structure layer and a translucent substrate, the semiconductor structure layer including a light-emitting layer, the translucent substrate being disposed on the semiconductor structure layer and having a plate shape: a wavelength converter bonding step of bonding a wavelength converter to an upper surface of the translucent substrate; a light scattering resin application step of applying a light scattering resin onto the one main surface of the substrate; and a resin curing step of heating the light scattering resin to form a light scattering part that covers from a side surface of the wavelength converter to a side surface of the light-emitting element and the one main surface of the substrate. In the resin curing step, the light scattering resin is continuously heated to a predetermined temperature in one step to form the light scattering part in which a first inclined surface inclined outwardly downward from an upper end of the side surface of the wavelength converter, a flat surface formed continuously with the first inclined surface and extending along the one main surface, and a second inclined surface formed continuously with an outer end of the flat surface and inclined outwardly upward are integrally formed. The flat surface is formed such that a height position of the flat surface from the one main surface of the substrate is lower than a lower surface of the wavelength converter.

### BRIEF DESCRIPTION OF THE DRAWINGS

FIG. 1 is a top view of a light-emitting device according to Example 1 of the present invention.

FIG. 2 is a cross-sectional view of the light-emitting device according to Example 1 of the present invention.

FIG. 3 is a bottom view of a light-emitting element used for the light-emitting device according to Example 1 of the present invention.

FIG. 4 is a cross-sectional view of the light-emitting element used for the light-emitting device according to Example 1 of the present invention.

FIG. 5 is a diagram illustrating a manufacturing flow of the light-emitting device according to Example 1 of the present invention.

FIG. 6 is a cross-sectional view in manufacturing the light-emitting device according to Example 1 of the present invention.

FIG. 7 is a cross-sectional view in manufacturing the light-emitting device according to Example 1 of the present invention.

FIG. 8 is a cross-sectional view in manufacturing the light-emitting device according to Example 1 of the present invention.

FIG. 9 is a cross-sectional view in manufacturing the light-emitting device according to Example 1 of the present invention.

FIG. 10 is a cross-sectional view in manufacturing the light-emitting device according to Example 1 of the present invention.

FIG. 11 is a cross-sectional view in manufacturing the light-emitting device according to Example 1 of the present invention.

FIG. 12 is a cross-sectional view of a light-emitting device of Comparative Example 1.

FIG. 13 is a cross-sectional view of the light-emitting device of Comparative Example 2.

FIG. 14 is a diagram showing a luminance distribution of the light-emitting device according to Example 1 of the present invention.

FIG. 15 is an enlarged cross-sectional view of a light scattering part of the light-emitting device according to Example 1 of the present invention.

FIG. 16 is a top view of a light-emitting device according to Example 2 of the present invention.

FIG. 17 is a cross-sectional view of the light-emitting device according to Example 2 of the present invention.

FIG. 18 is a top view of a light-emitting device according to Example 3 of the present invention.

FIG. 19 is a cross-sectional view of the light-emitting device according to Example 3 of the present invention.

FIG. 20 is a cross-sectional view of a light-emitting device according to

Modification of the present invention. DESCRIPTION OF PREFERRED EMBODIMENTS

The following describes examples of the present invention in detail. Note that the same reference numerals are given to substantially identical or equivalent parts in the following description and the accompanying drawings.

### Example 1

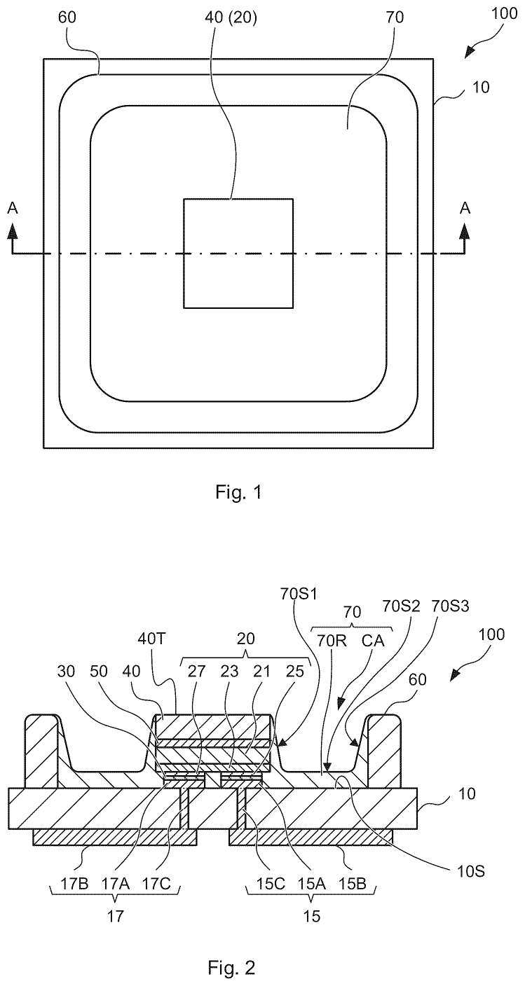

With reference to FIG. 1 and FIG. 2, a constitution of a light-emitting device 100 according to Example 1 will be described. FIG. 1 is a top view of the light-emitting device 100 according to Example 1. FIG. 2 is a cross-sectional view taken along a line A-A of the light-emitting device 100 illustrated in FIG. 1.

### Light-Emitting Device 100

The light-emitting device 100 includes a flat plate-shaped substrate 10 having one main surface, a light-emitting element 20 mounted on the one main surface of the substrate 10, that is, an upper surface 10S, a wavelength converter 40 disposed on a surface opposite to a surface opposed to the substrate 10 of the light-emitting element 20, that is, an upper surface of the light-emitting element 20, and a light scattering material 70R that extends to cover a side surface of the light-emitting element 20 and a side surface of the wavelength converter 40 and cover the upper surface 10S of the substrate 10. The light-emitting device 100 includes a frame body 60 formed in an outer edge region of the upper surface 10S of the substrate 10 so as to surround the light-emitting element 20 and the wavelength converter 40.

In the following description, a direction on a side of the upper surface 10S of the substrate 10 is referred to as above/upward, and a surface on a lower surface side is referred to as below/downward.

### Substrate 10

The substrate 10 is a flat plate-shaped substrate having an insulating property. The substrate 10 includes a pair of electrodes, a first electrode 15 and a second electrode 17, each of which is formed from the upper surface 10S to the lower surface and formed to be separated from one another. For the substrate 10, for example, a ceramic such as aluminum nitride (AlN), alumina (Al₂O₃), or the like can be used as a base material. For the substrate 10, alumina mixed with a glass material may also be used as a base material. In Example 1, AlN having an insulating property and having a high thermal conductivity is selected as a base material to form the substrate 10.

Each of the first electrode 15 and the second electrode 17 has a first loading electrode 15A and a second loading electrode 17A formed on the upper surface 10S of the substrate 10, a first mounting electrode 15B and a second mounting electrode 17B formed on the lower surface of the substrate 10, and a first through electrode 15C and a second through electrode 17C that penetrate the substrate 10 and electrically connect the respective loading electrodes and mounting electrodes, respectively. The first electrode 15 and the second electrode 17 are each formed of a conductive metal. In Example 1, a metal made of copper (Cu) is used for each of the first electrode 15 and the second electrode 17. Nickel (Ni) and gold (Au) are laminated in this order on an exposed surface of each of the first electrode 15 and the second electrode 17.

In Example 1, the substrate 10 as well as the first electrode 15 and the second electrode 17 are formed of a low temperature co-fired ceramics (LTCC) substrate obtained by co-firing an electrode pattern of Cu and a ceramic substrate. A conductive metal other than Cu, such as tungsten (W), silver (Ag), or the like may be used as the first electrode 15 and the second electrode 17.

In the substrate 10, the upper surface 10S on which the first loading electrode 15A and the second loading electrode 17A are formed functions as an element-loading surface on which the light-emitting element 20 is loaded, and the lower surface on which the first mounting electrode 15B and the second mounting electrode 17B are formed functions as a mounting surface to a mounting substrate.

### Light-Emitting Element 20

The light-emitting element 20 is a semiconductor light-emitting element such as a light emitting diode (LED) disposed on the upper surface 10S of the substrate 10. In Example 1, an LED element that emits blue light is used as the light-emitting element 20.

The light-emitting element 20 has a structure that includes a plate-shaped growth substrate 21 having a translucency, a semiconductor structure layer 23 including a light-emitting layer formed on a lower surface of the growth substrate 21, and a cathode electrode 25 and an anode electrode 27, which are a pair of electrodes formed on a surface opposite to a surface in contact with the growth substrate 21, that is, a lower surface, of the semiconductor structure layer 23.

The light-emitting element 20 is mounted in such an orientation that the lower surface of the growth substrate 21 on which the semiconductor structure layer 23 is formed is opposed to the upper surface 10S of the substrate 10. In the light-emitting element 20, each of the cathode electrode 25 and the anode electrode 27 is bonded to the first loading electrode 15A and the second loading electrode 17A formed on the upper surface 10S of the substrate 10, respectively, via the element bonding layers 30.

That is, the light-emitting element 20 is a flip-chip type light-emitting element in which a surface with the semiconductor structure layer 23 as an active face formed is inverted and bonded to the substrate 10. In other words, the light-emitting element 20 includes the semiconductor structure layer 23 disposed on the one main surface of the substrate 10, that is, the upper surface 10S and including the light-emitting layer, and the plate-shaped and translucent growth substrate 21 disposed on the semiconductor structure layer 23.

In the light-emitting element 20, light emitted from the semiconductor structure layer 23 formed on the lower surface of the growth substrate 21 passes through the growth substrate 21 and is emitted from an upper surface of the growth substrate 21. That is, the upper surface of the growth substrate 21 functions as a light extraction surface of the light-emitting element 20.

### Structure of Light-Emitting Element 20

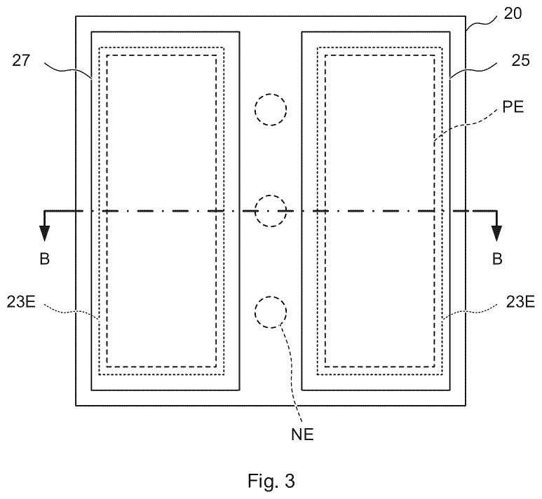

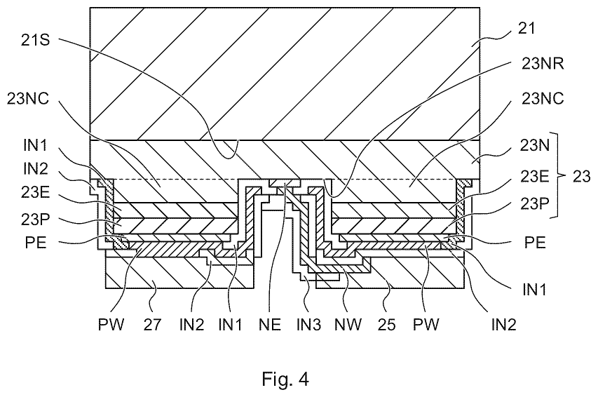

An exemplary structure of the light-emitting element 20 will be described using FIG. 3 and FIG. 4. FIG. 3 is a bottom view of the light-emitting element 20 used in the light-emitting device 100 according to Example 1 of the light-emitting element 20. FIG. 4 is a cross-sectional view taken along a line B-B of the light-emitting element 20 shown in FIG. 3. In FIG. 3 and FIG. 4, only the light-emitting element 20 is illustrated.

In the light-emitting element 20, for example, an n-type semiconductor layer 23N having an epitaxially grown gallium nitride (GaN)-based composition, light-emitting layers 23E having a quantum well structure, and p-type semiconductor layers 23P are each laminated in this order on a lower surface 21S, which is one surface of the translucent growth substrate 21 made of sapphire. In Example 1, a sapphire substrate having a thickness of, for example, about 70 μm is used for the growth substrate 21.

The n-type semiconductor layer 23N is formed over the entire region of the lower surface 21S of the growth substrate 21. That is, the n-type semiconductor layer 23N is formed so as to cover the entire lower surface 21S of the growth substrate 21. As shown in FIG. 3 and FIG. 4, the n-type semiconductor layer 23N has two projecting portions 23NC on a lower surface that are spaced apart from one another and each have a rectangular planar shape. A recessed portion 23NR is formed between the two projecting portions 23NC on the lower surface of the n-type semiconductor layer 23N. The light-emitting layer 23E and the p-type semiconductor layer 23P are formed so as to be laminated in this order on a lower surface of the projecting portion 23NC of the n-type semiconductor layer 23N.

The p-side electrodes PE are formed on lower surfaces of the p-type semiconductor layers 23P and electrically connected to the p-type semiconductor layers 23P so as to have an ohmic connection. An n-side electrode NE is formed on a surface of the recessed portion 23NR on the lower surface of the n-type semiconductor layer 23N and electrically connected to the n-type semiconductor layer 23N so as to have an ohmic connection.

The first insulating layers IN1 are formed on a surface of the semiconductor structure layer 23 formed of the n-type semiconductor layer 23N, the light-emitting layers 23E, and the p-type semiconductor layers 23P so as to expose at least a part of lower surfaces of the p-side electrodes PE and the n-side electrode NE.

The p-side transition wirings PW are formed from the exposed surfaces of the p-side electrodes PE of the first insulating layers IN1 to surfaces of the first insulating layers IN1 formed on an inner surface of the recessed portion 23NR.

The second insulating layers IN2 are formed so as to cover the first insulating layers IN1 and the p-side transition wirings PW. The second insulating layer IN2 has an opening exposing a lower surface of the p-side transition wiring PW in a portion below one projecting portion 23NC (the projecting portion 23NC on the left side of FIG. 4).

An n-side transition wiring NW is formed from the lower surface of the n-side electrode NE to a lower surface of the second insulating layer IN2 below the other projecting portion 23NC (the projecting portion 23NC on the right side of FIG. 4).

A third insulating layer IN3 is formed so as to cover the n-side transition wiring NW. The third insulating layer IN3 is formed below the other projecting portion 23NC (the projecting portion 23NC on the right side of FIG. 4) so as to expose a surface of the n-side transition wiring NW.

The cathode electrode 25 is formed on a lower surface of the n-side transition wiring NW exposed below the other projecting portion 23NC of the n-type semiconductor layer 23N. The anode electrode 27 is formed on the lower surface of the p-side transition wiring PW exposed below the one projecting portion 23NC (the projecting portion 23NC on the left side of FIG. 4) of the n-type semiconductor layer 23N.

The anode electrode 27 is electrically connected to the p-side transition wiring PW and is electrically connected to the p-type semiconductor layer 23P via the p-side transition wiring PW. The cathode electrode 25 is electrically connected to the n-side transition wiring NW and is electrically connected to the n-type semiconductor layer 23N via the n-side transition wiring NW.

The above-described p-side electrode PE includes, for example, an ohmic electrode layer including an ITO (indium tin oxide) layer and a light-reflective electrode layer including a layer of silver (Ag), rhodium (Rh), or the like. The p-side transition wiring PW and the n-side transition wiring NW are, for example, light-reflective wiring layers of aluminum (Al) or the like. The first insulating layer IN1 to the third insulating layer IN3 are, for example, translucent insulating layers of silicon oxide (SiO₂) or the like. The p-side electrode PE, the p-side transition wiring PW, and the n-side transition wiring NW function as a conductive light reflection layer that reflects light emitted from the light-emitting layer 23E in a direction of the growth substrate 21. In other words, the light-emitting element 20 has the cathode electrode 25 and the anode electrode 27, which are a pair of electrodes, on the lower surface of the semiconductor structure layer 23, and has the p-side electrodes PE, the p-side transition wirings PW, and the n-side transition wiring NW, which function as a conductive light reflection layer, between the semiconductor structure layer 23 and the cathode electrode 25 with the anode electrode 27.

In Example 1, the light-emitting device 100 is manufactured using the light-emitting element 20 having the above-described structure. The above-described structure of the light-emitting element 20 is merely one example.

### Element Bonding Layer 30

Again, reference is made to FIG. 1 and FIG. 2.

As described above, the light-emitting element 20 is disposed on the upper surface 10S of the substrate 10 in such an orientation that the lower surface 21S of the growth substrate 21 on which the semiconductor structure layer 23 is formed is opposed to the upper surface 10S of the substrate 10. The cathode electrode 25 and the anode electrode 27 of the light-emitting element 20 are bonded to the first loading electrode 15A and the second loading electrode 17A of the substrate 10, respectively, via the element bonding layers 30.

The element bonding layer 30 is a bonding layer that has a conductivity and bonds the first loading electrode 15A and the second loading electrode 17A of the substrate 10 to the cathode electrode 25 and the anode electrode 27 of the light-emitting element 20, respectively. In Example 1, a bonding of the light-emitting element 20 is performed using a eutectic layer of gold tin (AuSn) for the element bonding layer 30. This causes the first mounting electrode 15B to function as a cathode electrode of the light-emitting device 100 and the second mounting electrode 17B to function as an anode electrode of the light-emitting device 100.

As another example, a solder paste, a silver paste, or the like can be used for the element bonding layer 30, which can be appropriately selected depending on a bonding material with the mounting substrate used when mounting the light-emitting device 100.

### Wavelength Converter 40

The wavelength converter 40 has a plate-like shape and is bonded onto the upper surface of the light-emitting element 20 via an adhesive layer 50. The wavelength converter 40 converts a wavelength of a part of emitted light of the light-emitting element 20 that enters through the lower surface, which is a surface opposed to the light-emitting element 20, and emits it from an upper surface 40T.

The wavelength converter 40 is made of, for example, a polycrystalline ceramic fired body in which phosphor particles and ceramic particles as a binder is mixed and fired. The wavelength converter 40 has a light scattering property that scatters light entering the interior and light generated inside at crystal grain boundary surfaces. The wavelength converter 40 of this example is adjusted such that light entering through one surface is mainly emitted from the other surface opposed thereto while being scattered.

With such a wavelength converter 40, the light emitted from the light-emitting element 20 enters through the lower surface of the wavelength converter 40 (light-entering surface) and is emitted from the upper surface 40T (light-exiting surface) while forwardly diffusing. On the other hand, light in which a wavelength is converted with the phosphor particles contained in the wavelength converter 40 is mainly emitted from both the upper and lower surfaces of the wavelength converter 40. Of this, the light emitted from the lower surface of the wavelength converter 40 enters through the upper surface of the light-emitting element 20 to be reflected by the p-side electrode PE, the p-side transition wiring PW, and the n-side transition wiring NW, which are also the light reflection layer of the light-emitting element 20, and is emitted again from the upper surface of the light-emitting element 20 to enter through the lower surface of the wavelength converter 40, and finally emitted from the upper surface 40T of the wavelength converter 40. Light of an amount corresponding to the scattering property is emitted from the side surfaces of the wavelength converter 40.

In Example 1, the wavelength converter 40 is produced using particles of yttrium aluminum gamet (YAG:Ce, Y₃Al₅O₁₂Ce) doped with cerium (Ce) as phosphor particles of the wavelength converter 40 and particles of alumina as a binder. In Example 1, the content rate of the phosphor particles is adjusted such that the wavelength converter 40 converts a wavelength of a part of blue light emitted from the light-emitting element 20 into yellow light so as to emits white light. The wavelength converter 40 is formed to have an outer shape in a top view that is approximately the same as an outer shape of the light-emitting element 20 in a top view. The wavelength converter 40 is formed to have a thickness of about 220 μm.

### Adhesive Layer 50

The adhesive layer 50 is a translucent resin that bonds the upper surface, which is the light-exiting surface, of the light-emitting element 20, to the lower surface, which is the light-entering surface, of the wavelength converter 40. In Example 1, a thermosetting silicone resin having a translucency is used as the adhesive layer 50. In addition to the silicone resin, an epoxy resin or an acrylic resin can also be used for the adhesive layer 50.

In Example 1, the adhesive layer 50 is formed between the upper surface of the light-emitting element 20 and the wavelength converter 40 so as to have a thickness of about 10 μm.

### Frame Body 60

The frame body 60 is formed in an annular shape on the upper surface 10S of the substrate 10 so as to surround the light-emitting element 20 and the wavelength converter 40. The frame body 60 is, for example, a resin material having a reflectivity to the light emitted from the light-emitting element 20 and the wavelength converter 40. The frame body 60 has a height equal to or higher than that of the upper surface 40T of the wavelength converter 40 such that the light emitted from the light-emitting element 20 and the wavelength converter 40 can be emitted to the front of the light-emitting device 100. In Example 1, a thermosetting silicone resin mixed with titanium oxide (TiO₂) particles, which are light scattering particles having a particle size of 200 nm to 300 nm, is used as the frame body 60. In Example 1, a silicone resin containing TiO₂ particles at about 60 to 80 wt % is formed into the frame body 60. The frame body 60 can be integrally molded with the substrate 10. In that case, the frame body 60 is formed of the same material as the substrate 10.

### Light Scattering Part 70

A light scattering part 70 is formed in a region surrounded by the frame body 60 on the upper surface 10S of the substrate 10.

As shown in FIG. 2, the light scattering part 70 is formed of: the light scattering material 70R that exposes the upper surface 40T of the wavelength converter 40, integrally covers a surface from an upper end of the side surface of the wavelength converter 40 (an outer edge of the upper surface 40T) to the upper surface 10S of the substrate 10 and an upper end of an inner surface of the frame body 60, and has an opening at the top; and a recessed space CA that is surrounded by the light scattering material 70R and opened upward.

The light scattering material 70R is, for example, a resin material that includes light scattering particles and scatters the light emitted from the light-emitting element 20 and the wavelength converter 40. In Example 1, a thermosetting silicone resin mixed with TiO₂ particles, which are light scattering particles having a particle size of 200 nm to 300 nm, is used as the light scattering material 70R. In Example 1, the light scattering material 70R is formed using a silicone resin containing TiO₂ particles at about 8 to 30 wt %.

The light scattering material 70R has a first inclined surface 70S1 inclined outwardly downward from the upper end of the side surface of the wavelength converter 40. The light scattering material 70R has a flat surface 70S2 that is continuous with the first inclined surface 70S1 and extends substantially parallel to the upper surface 10S along the upper surface 10S of the substrate 10. The light scattering material 70R has a second inclined surface 70S3 that is continuous with the flat surface 70S2 and inclined upward toward the upper end of the inner surface of the frame body 60, that is. inclined outwardly upward. The space CA is a space surrounded by the first inclined surface 70S1, the flat surface 70S2, and the second inclined surface 70S3.

In Example 1, the largest thickness of a portion of the light scattering material 70R covering the side surfaces of the light-emitting element 20 and the wavelength converter 40 is about 3 to 4 μm from the side surfaces of the light-emitting element 20 and the wavelength converter 40. The largest thickness of a portion of the light scattering material 70R covering the inner surface of the frame body 60 is about 5 to 10 μm from the inner surface of the frame body 60.

The light emitted from the side surface of the light-emitting element 20 and the light emitted from the side surface of the wavelength converter 40 reach the first inclined surface 70S1 while being scattered inside the light scattering material 70R, are emitted from the first inclined surface 70S1 into the space CA. and are emitted upward from an opening of the light scattering part 70.

Therefore, in the light-emitting device 100 according to Example 1, light can also be extracted from the space CA. That is, in the light-emitting device 100 according to Example 1, a region surrounded by the frame body 60 in a top view functions as a light extraction surface. Therefore, the light-emitting device 100 can increase an area of the light extraction surface and improve the total luminous flux of the light emitted from the light-emitting device 100. An area of the light scattering part 70 in a top view of this example is about eight times that of the upper surface 40T of the wavelength converter 40. The area of the light scattering part 70 is preferably about 4 to 12 times that of the wavelength converter 40. When it is less than three times, a slope of the first inclined surface 70S1 is moderate, which reduces a quantity of light emitted into the space CA. When it is more than 10 times, the area of the space CA may be too large, resulting in a dark section. The shape is preferably a proportionally enlarged shape of an outer peripheral shape of the light-emitting element 20 and the wavelength converter 40 in a laminated arrangement.

A height position of the flat surface 70S2 of the light scattering material 70R is preferably set at a position lower than a height of the upper surface of the growth substrate 21 by ½ or more of a thickness of the growth substrate 21 such that sufficient light is emitted from the space CA. In this example, since the thickness of the growth substrate 21 is about 70 μm, it is preferable that the height position of the flat surface 70S2 of the light scattering material 70R is set at a position lower than the upper surface of the growth substrate 21 by about 35 μm or more.

Further, it is more preferable that the height position of the flat surface 70S2 of the light scattering material 70R is set at a position lower than the height of the upper surface of the growth substrate 21 by ⅔ or more of the thickness of the growth substrate 21. In this example, it is more preferable that the height position of the flat surface 70S2 is set at a position lower than the upper surface of the growth substrate 21 by about 47 μm or more.

It is preferable that the height position of the flat surface 70S2 of the light scattering material 70R is set at a position higher than the upper surface of the semiconductor structure layer 23, that is, the lower surface 21S of the growth substrate 21. This is because, when the height position of the flat surface 70S2 of the light scattering material 70R is set at a position lower than the lower surface 21S of the growth substrate 21, a proportion of the blue light passing through the light scattering material 70R to the light emitted from the semiconductor structure layer 23 increases.

### Method for Manufacturing Light-Emitting Device 100

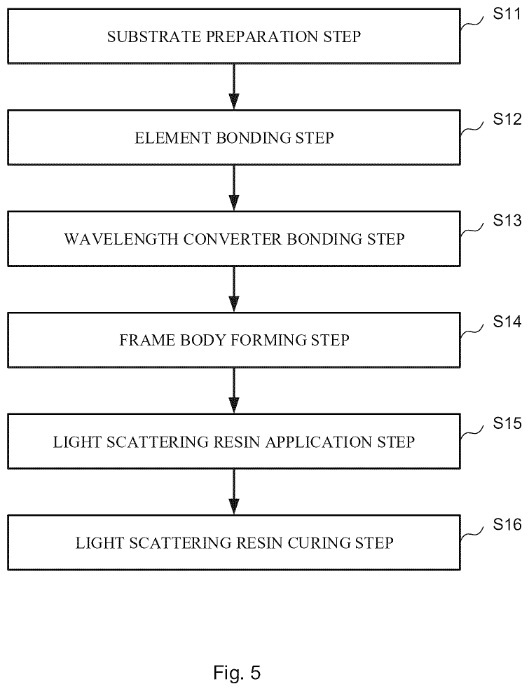

Next, the method for manufacturing the light-emitting device 100 of Example 1 will be described using FIG. 5 to FIG. 11.

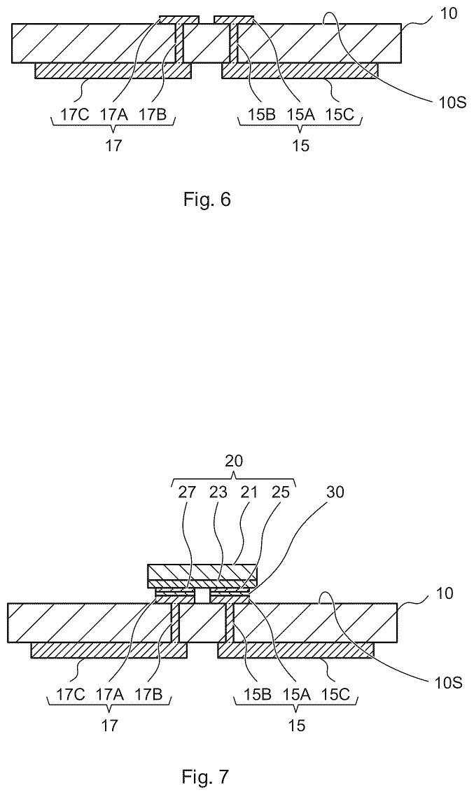

FIG. 5 is a diagram illustrating a manufacturing flow of the light-emitting device 100 according to Example 1 of the present invention. FIG. 6 to FIG. 11 are cross-sectional views of the light-emitting device 100 in each step of the manufacturing process shown in FIG. 5. FIG. 6 to FIG. 11 show cross sections taken along the line A-A shown in FIG. 1.

First, as shown in FIG. 6, a step of preparing the substrate 10 on which the first electrode 15 and the second electrode 17 are formed is performed (Step S11, a substrate preparation step). In this step, Cu electrode patterns of the first electrode 15 and the second electrode 17 are formed in through-holes and on the upper surface 10S and the lower surface of an AlN slurry sheet provided with the through-holes, and subjected to firing (low-temperature co-firing), and then Ni plating and Au plating are performed on the Cu electrode patterns to form the substrate 10.

Next, as shown in FIG. 7, a step of bonding the light-emitting element 20 onto the upper surface 10S of the substrate 10 is performed (Step S12, an element bonding step). In this step, first, a paste in which AuSn particles and flux are mixed, which is a raw material of the element bonding layer 30, is applied on the upper surfaces of the first loading electrode 15A and the second loading electrode 17A. Next, the light-emitting element 20 is placed on the substrate 10 such that each of the cathode electrode 25 and the anode electrode 27 of the light-emitting element 20 is opposed to each of the first loading electrode 15A and the second loading electrode 17A via the paste.

Then, the substrate 10 in this state is heated to about 300° C. in a reflow furnace to melt the AuSn particles in the paste applied on the first loading electrode 15A and the second loading electrode 17A and cause a eutectic reaction, thereby forming the element bonding layer 30 that bonds the respective electrodes of the light-emitting element 20 and the respective loading electrodes of the substrate 10.

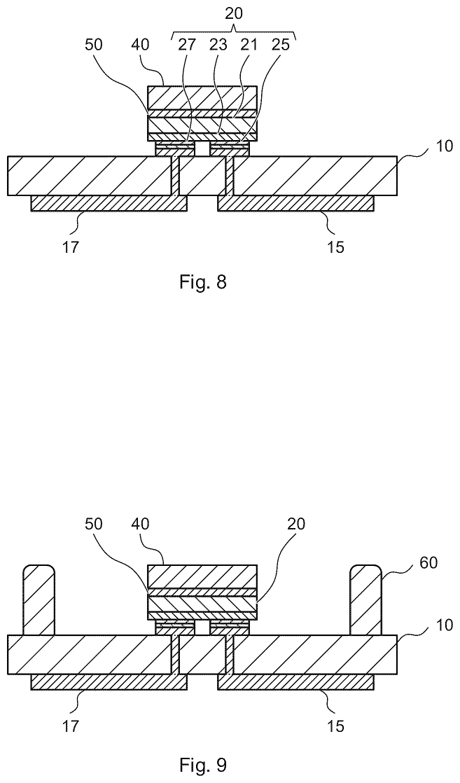

Next, as shown in FIG. 8, a step of bonding the wavelength converter 40 onto the upper surface of the light-emitting element 20 is performed (Step S13, a wavelength converter bonding step). In this step, first, an uncured liquid silicone resin, which is a raw material of the adhesive layer 50, is applied on the upper surface of the light-emitting element 20. Next, the wavelength converter 40 is placed so as to be in contact with the silicone resin, and pressed toward the upper surface of the light-emitting element 20. The wavelength converter 40 is placed in such a place that the respective outer shapes of the wavelength converter 40 and the light-emitting element 20 are substantially identical in a top view.

Then, the substrate 10 in this state is heated at 170° C. for 10 minutes to temporarily cure the silicone resin. The silicone resin may be fully cured in this step, or may remain uncured and be simultaneously cured at the time of forming the frame body 60 described later.

Next, as shown in FIG. 9, a step of forming the frame body 60 on the upper surface 10S of the substrate 10 is performed (Step S14, a frame body forming step). In this step, first, a dispenser filled with an uncured silicone resin in which TiO₂ particles are dispersed, which is a raw material of the frame body 60, is used to draw with the raw material of the frame body 60 on the upper surface 10S of the substrate 10 so as to surround the light-emitting element 20 and the wavelength converter 40.

Then, the substrate 10 in this state is heated at 150° C. for 60 minutes to cure the silicone resin to form the frame body 60. A molded frame body 60 may be bonded with a silicone resin. In this case, it is carried out simultaneously in the aforementioned Step 13. When the substrate 10 provided with the frame body 60 is used, the frame body forming step can be omitted.

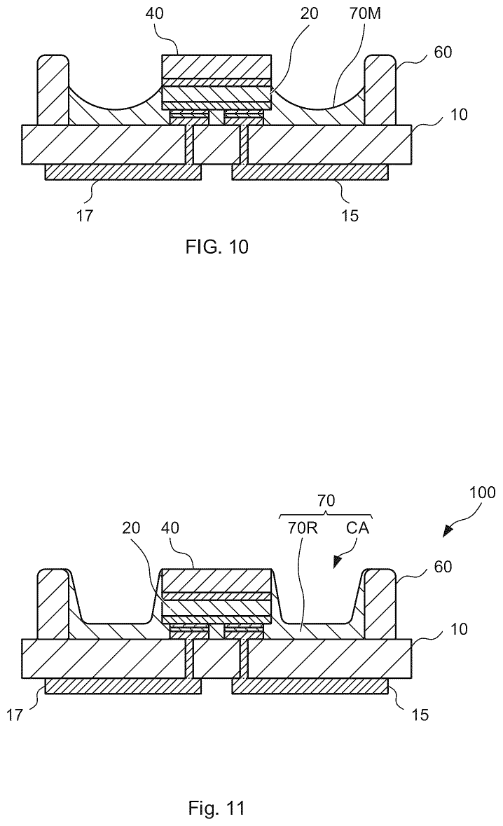

Next, as shown in FIG. 10, a step of applying a light scattering resin 70M, which is a raw material of the light scattering material 70R, to a region surrounded by the frame body 60 on the upper surface 10S of the substrate 10 is performed (Step S15, a light scattering resin application step). In this step, a dispenser filled with an uncured silicone resin in which TiO₂ particles are dispersed, which is the light scattering resin 70M, is used to apply the light scattering resin 70M between the light-emitting element 20 and the frame body 60.

An application amount of the light scattering resin 70M is adjusted such that after curing of the silicone resin, the light scattering material 70R has the above-described shape, in particular, the height position of the flat surface 70S2 of the light scattering material 70R is at a position lower than the upper surface of the light-emitting element 20. When the frame body 60 is light-reflective, at the time of applying the light scattering resin 70M, an end portion of the light scattering resin 70M does not have to fully crawl up to the upper end of the side surface of the wavelength converter 40 and the upper end of the inner surface of the frame body 60.

Next, as shown in FIG. 11, a step of curing the light scattering resin 70M to form the light scattering material 70R is performed (Step S16, a light scattering resin curing step). In this step, the substrate 10 with the light scattering resin 70M applied is heated at 150° C. for 60 minutes to cure the silicone resin to form the light scattering material 70R.

In this step, rapidly heating the substrate 10 with the light scattering resin 70M applied causes the end portion of the light scattering resin 70M to fully crawl up to the upper end of the side surface of the wavelength converter 40 and the upper end of the inner surface of the frame body 60.

Usually, when a silicone resin is thermally cured, for example, the temperature is increased from a room temperature state to 100° C. in a heating furnace or the like to perform a preheating of the silicone resin for about 30 minutes, and then the temperature is further increased to 150° C. to perform a main heating for about 30 minutes to fully cure the silicone resin.

In Example 1, the light scattering resin 70M is fully cured by heating for 60 minutes by increasing the temperature from the room temperature state to 150° C. in a heating furnace or the like, without performing the preheating described above. That is, the light scattering resin 70M is continuously heated to a predetermined temperature in one step to cure the light scattering resin 70M.

This allows the end portion of the light scattering resin 70M to fully crawl up to the upper end of the side surface of the wavelength converter 40 and the upper end of the inner surface of the frame body 60. Specifically, the uncured silicone resin contained in the light scattering resin 70M expands with a decrease in viscosity at around 100° C., and then a crosslinked structure of the silicone resin is formed, thereby being cured with a volume shrinkage. In Example 1, heating by increasing the temperature from the room temperature state to 150° C. in one step allows the end portion of the uncured silicone resin contained in the light scattering resin 70M to crawl up to the side surface of the wavelength converter 40 and the side surface of the frame body 60, and to be cured into the light scattering material 70R while keeping the crawling up. This enables a formation of the light scattering part 70 including the light scattering material 70R that integrally covers the surface from the upper end of the side surface of the wavelength converter 40 to the upper surface 10S of the substrate 10 and the upper end of the side surface of the frame body 60, and the recessed space CA that is surrounded by the surface of the light scattering material 70R and opened upward.

In this step, for example, the substrate 10 with the light scattering resin 70M applied may be placed for a predetermined period of time in a heating furnace that is kept at 150° C. and is continuously operated.

The light-emitting device 100 of Example 1 is manufactured by performing Step S11 to Step S16 described above.

### Introduction of Comparative Examples

Next, Comparative Example 1 and Comparative Example 2 will be described. Comparative Example 1 and Comparative Example 2 are similar to Example 1 except for a part, and therefore only the differences will be described.

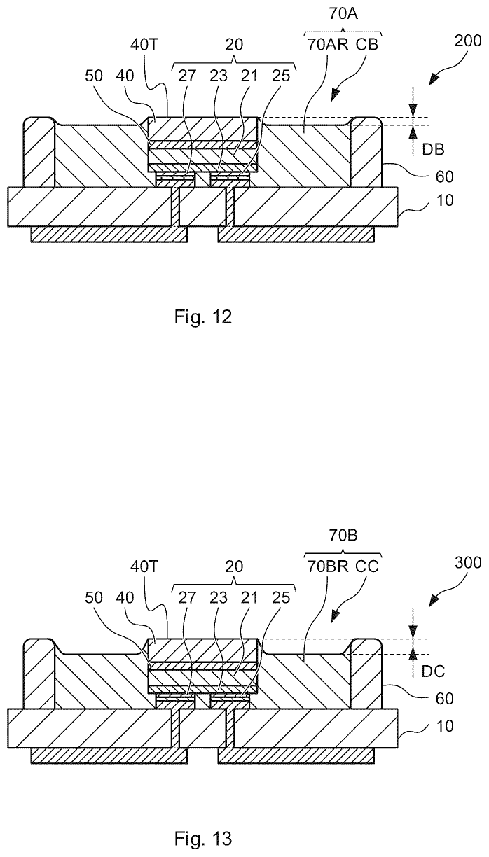

FIG. 12 is a cross-sectional view of a light-emitting device 200 as Comparative Example 1. FIG. 12 is the cross-sectional view at a position corresponding to the line A-A of the light-emitting device 100 shown in FIG. 1.

FIG. 13 is a cross-sectional view of a light-emitting device 300 as Comparative Example 2. FIG. 13 is the cross-sectional view at a position corresponding to the line A-A of the light-emitting device 100 shown in FIG. 1.

The light-emitting device 200 of Comparative Example 1 and the light-emitting device 300 of Comparative Example 2 use the same as the substrate 10, the light-emitting element 20, the wavelength converter 40, and the frame body 60 used in the light-emitting device 100 of Example 1.

### Comparative Example 1

In the light-emitting device 200 of Comparative Example 1, a height position of a bottom surface (flat surface) of a recessed space CB of the light scattering part 70 is substantially equal to the height of the upper surface 40T of the wavelength converter 40. Specifically, a height DB of the bottom surface of the recessed space CB of the light scattering part 70 is set to a position about 63 μm lower than the upper surface 40T of the wavelength converter 40 in a direction of the substrate 10.

Such a light-emitting device 200 can be manufactured by increasing a filling amount of the light scattering resin 70M in the aforementioned Step S15. An offset of the height DB is caused by a resin sinking due to the volume shrinkage of the light scattering resin 70M, which is a precursor of the light scattering material 70R, during heat curing.

### Comparative Example 2

In the light-emitting device 300 of Comparative Example 2, a height position of a bottom surface (flat surface) of a recessed space CC of the light scattering part 70 is higher than the lower surface and lower than the upper surface of the wavelength converter 40. Specifically, a height DC of the bottom surface of the recessed space CC of the light scattering part 70 is set to a position about 140 μm lower than the upper surface 40T of the wavelength converter 40 in the direction of the substrate 10. Such a light-emitting device 300 can be manufactured by slightly increasing a filling amount of the light scattering resin 70M in the aforementioned Step S15.

### Experimental Results of Example 1 and Comparative Examples

Next, an optical output property of the light-emitting device 100 of Example 1 will be described in comparison with those of the light-emitting device 200 of Comparative Example 1 and the light-emitting device 300 of Comparative Example 2.

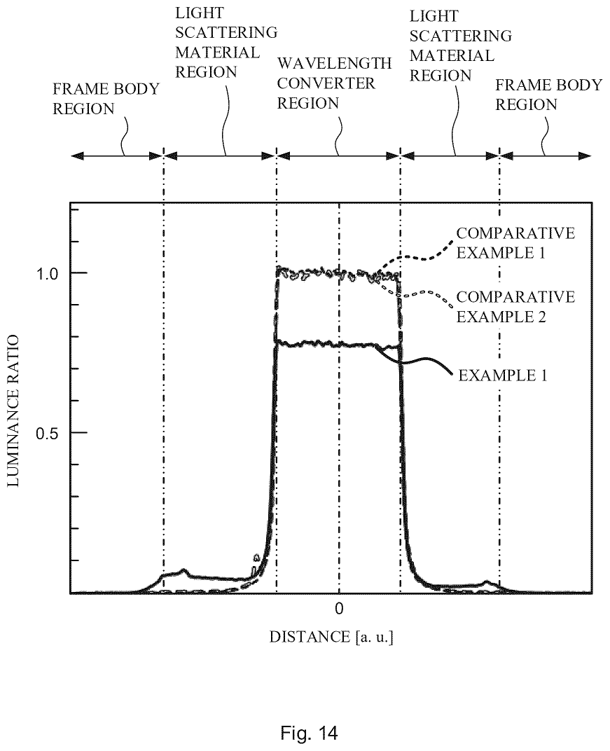

FIG. 14 is a diagram showing light emission luminance distributions in the respective top views of the light-emitting device 100 of Example 1, the light-emitting device 200 of Comparative Example 1, and the light-emitting device 300 of Comparative Example 2.

A horizontal axis of FIG. 14 shows a distance from a reference point 0 in a direction along the line A-A shown in FIG. 1. The point 0, which is the reference point indicated by a dash-dot line on the horizontal axis of FIG. 14, is a center point of the light extraction surface of each of the light-emitting devices 100, 200, and 300 (the center of the upper surface 40T of the wavelength converter 40). Among regions indicated by dash-dot-dot lines on the horizontal axis of FIG. 14, a wavelength converter region indicates a region inward from an outer end of the upper surface 40T of each wavelength converter 40, and a frame body region indicates a region outward from the inner surface of each frame body 60. A light scattering material region indicates a formation region of the light scattering material 70R in each of the light-emitting devices in a top view. That is, the light scattering material regions indicate regions in which the spaces CA, CB, and CC are formed in the top views of the respective light-emitting devices.

The vertical axis of FIG. 14 shows luminance values of light of each of the light-emitting devices 100, 200, and 300 when measured vertically downward from above at the respective positions shown on the horizontal axis, which are normalized by the luminance value of Comparative Example 1 (the mutual intensity relation is maintained).

In FIG. 14, a graph indicated by a solid line shows a luminance distribution of the light-emitting device 100, a dashed line graph shows a luminance distribution of the light-emitting device 200, and an outlined dashed line graph shows a luminance distribution of the light-emitting device 300.

In Example 1, the wavelength converter region, which is a region of the upper surface 40T of the wavelength converter 40, had a luminance ratio of about 0.8, and the light scattering material region, which is a region of the space CA from the outer end of the upper surface 40T of the wavelength converter 40 to the inner surface of the frame body 60, had a luminance ratio of 0.05 to 0.1.

In contrast, in the light-emitting device 200 of Comparative Example 1 and the light-emitting device 300 of Comparative Example 2, the luminance ratio of the wavelength converter region, which is the region of the upper surface 40T of the wavelength converter 40, was equivalent to about 1.0 in each case. It can be seen that the luminance ratio of the light scattering material region, that is, regions of the spaces CB and CC, is approximately 0, and no light is emitted. In Comparative Example 1 and Comparative Example 2, no difference in the luminance ratio due to the heights DB and DC from the upper surface 40T of the wavelength converter 40 to the bottom surfaces of the spaces CB and CC of the recessed light scattering part 70 can be seen.

Next, a total luminous flux of each light-emitting device will be described. The total luminous flux is described by a percentage normalized by a total luminous flux of Comparative Example 1. The light-emitting device 100 of Example 1 had a total luminous flux of 105%, and the light-emitting device 200 of Comparative Example 1 and the light-emitting device 300 of Comparative Example 2 had total luminous fluxes of 100% and 101%, respectively.

As described above, the luminance ratio of the wavelength converter region of the light-emitting device 100 of Example 1 is lower than those of Comparative Example 1 and Comparative Example 2, and the luminance ratio of the light scattering material region is higher. In contrast, the total luminous flux of Example 1 is larger than those of Comparative Example 1 and Comparative Example 2. That is, the light-emitting device 100 of Example 1 is a light-emitting device capable of suppressing the luminance of the wavelength converter region while improving the total luminous flux. In other words, it is a light-emitting device with the light scattering material region as the light-exiting surface in addition to the wavelength converter region.

### Light-Emitting Optical Path of Light-Emitting Device 100

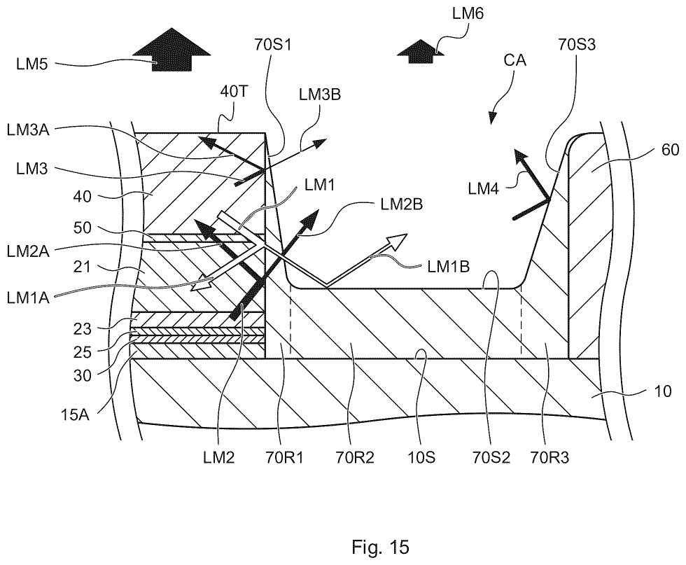

Next, an optical path of the light emitted from the light-emitting device 100 of Example 1 having the luminance distribution and a total luminous flux amount as described above will be described using FIG. 15.

FIG. 15 is a diagram illustrating optical paths of lights LM1 to LM6, which are part of the light generated inside the light-emitting device 100, in a cross section in which the periphery of the space CA of the light-emitting device 100 is enlarged. FIG. 15 is an enlarged cross-sectional view of the cross section indicated by the line A-A in FIG. 1. Each of the lights LM1 to LM6 schematically describes only a representative light beam for the sake of simplicity of description.

As discussed above, the light scattering material 70R exposes the upper surface 40T of the wavelength converter 40 and integrally covers the surface from the upper end of the side surface of the wavelength converter 40 to the upper surface 10S of the substrate 10 and the upper end of the side surface of the frame body 60.

In the following description, a portion of the light scattering material 70R covering the side surface of the wavelength converter 40 and the side surface of the light-emitting element 20 is referred to as a first light scattering portion 70R1, a portion extending on the upper surface 10S of the substrate 10 is referred to as a second light scattering portion 70R2, and a portion covering the inner surface of the frame body 60 is referred to as a third light scattering portion 70R3.

In the following description, a surface of the first light scattering portion 70R1 that is inclined from the upper end of the side surface of the wavelength converter 40 toward the substrate 10 is referred to as a first inclined surface 70S1, a surface of the second light scattering portion 70R2 that extends along the upper surface 10S of the substrate 10 is referred to as a flat surface 70S2, and a surface of the third light scattering portion 70R3 that is inclined toward the upper end of the inner surface of the frame body 60 is referred to as a second inclined surface 70S3.

The first light scattering portion 70R1 is formed such that a thickness of the light scattering material 70R from the side surfaces of the wavelength converter 40 and the light-emitting element 20 gradually increases downward, from the upper end of the side surface of the wavelength converter 40.

The light LM1 indicates the light that reaches the side surface of the growth substrate 21 in the light emitted below the wavelength converter 40 in the light (converted light) emitted in all directions as fluorescence of yellow light by absorbing the blue light emitted from the light-emitting element 20.

The light LM1 enters the first light scattering portion 70R1 from the side surface of the growth substrate 21 of the light-emitting element 20. The light LM1 entering the first light scattering portion 70R1 is divided into a return light LM1A that is reflected by the first light scattering portion 70R1 and re-enters an inside of the growth substrate 21, and a passing light LM1B that passes through an inside of the first light scattering portion 70R1 while being scattered.

The return light LM1A is reflected by the p-side electrode PE, the p-side transition wiring PW, and the n-side transition wiring NW, which are also the light reflection layer of the light-emitting element 20, and reflected upward. The passing light LM1B is reflected by the light scattering material 70R and emitted from the space CA to an upper side of the light-emitting device 100.

The light LM2 is the light that reaches the side surface of the growth substrate 21 in the light emitted from the semiconductor structure layer 23 and the light in which the return light LM1A is reflected by the light reflection layer of the light-emitting element 20.

The light LM2 enters the first light scattering portion 70R1 from the side surface of the growth substrate 21 of the light-emitting element 20. The light LM2 entering the first light scattering portion 70R1 is divided into a return light LM2A that reflected by the first light scattering portion 70R1 and a passing light LM2B that passes through the inside of the first light scattering portion 70R1 while being scattered.

The return light LM2A enters the wavelength converter 40 and travels upward. The passing light LM2B is reflected by the light scattering material 70R and emitted from the space CA to the upper side of the light-emitting device 100.

The above-described light LM1 and light LM2 are lights that are guided through the non-scattering and translucent growth substrate 21 from every part of the lower surface of the wavelength converter 40 and the upper surface of the semiconductor structure layer 23 to reach the side surface of the growth substrate 21, and have a high quantity of light. Therefore. the quantity of light of the passing lights LM1B and LM2B also increase.

The light LM3 is the light that reaches the side surface in the light scattered near the side surface of the light scattering wavelength converter 40. The light LM3 enters the first light scattering portion 70R1 from the side surface of the wavelength converter 40 and is divided into a return light LM3A and a passing light LM3B.

The return light LM3A re-enters an inside of the wavelength converter 40 and travels upward.

The passing light LM3B is reflected by the light scattering material 70R and emitted from the space CA to the upper side of the light-emitting device 100.

The light LM3 is the light that can reach the side surface of the wavelength converter 40 after being scattered and thus has a low quantity of light (quantity lower than those of the light LM1 and the light LM2). The illustrated light LM3 is one example, and there are other lights that enter the side surface of the wavelength converter 40 from various orientations. Therefore, the return light LM3A and the passing light LM3B may be directed downward.

The light LM4 is the light that is reflected by the second inclined surface 70S3 of the light scattering material 70R and emitted to the upper side of the light-emitting device 100. The illustrated light LM4 is one example, and other similar lights are also present on various surfaces of the light scattering material 70R.

The light LM5 is the light emitted from the surface 40T of the wavelength converter 40 in the light emitted from the semiconductor light-emitting element 20 and the light emitted from a phosphor of the wavelength converter 40, and is a main light of the light-emitting device 100.

The light LM6 is the light that passes through the first light scattering part 70R1 from the side surfaces of the semiconductor light-emitting element 20 and the wavelength converter 40 and emitted from the space CA, and is a secondary light of the light-emitting device 100.

The light-emitting device 100 of Example 1 is provided with the light-emitting element 20 having the non-scattering and translucent growth substrate 21 and the light-reflective electrode layer on the lower surface of the semiconductor structure layer 23, and the wavelength converter 40 above the growth substrate 21 that has a light scattering property and contains a phosphor. This allows generating the light LM1 with a high quantity of light that reaches the side surface of the growth substrate 21 from the lower surface of the light converter and the light LM2 with a high quantity of light that reaches the side surface of the growth substrate 21 from the upper surface of the semiconductor structure layer 23.

The height of the flat surface 70S2 of the second light scattering part 70R2 of the light scattering material 70R is lower than the lower surface of the wavelength converter 40, resulting in a structure in which the first light scattering part 70R1 reaches the side surface of the growth substrate 21. This allows the passing lights LM1B and LM2B to be extracted from the first inclined surface 70S1 of the first light scattering part 70R1 to the space CA. At the same time, a reflecting surface made of the light scattering material 70R that allows the passing lights LM1B and LM2B to be emitted to an upper surface of the light-emitting device 100 is formed.

Thus, the light-emitting device 100 provided with the space CA serving as the light-exiting surface in the light scattering part 70 can extract the passing lights LM1B, LM2B, LM3B and the reflected light LM4, which are part of the light emitted from the semiconductor light-emitting element 20 and the wavelength converter 40, from the space CA as the light LM6. Extracting the light LM6 enables the reduced luminance of the light LM5 emitted from the upper surface 40T of the wavelength converter 40.

### Example 2

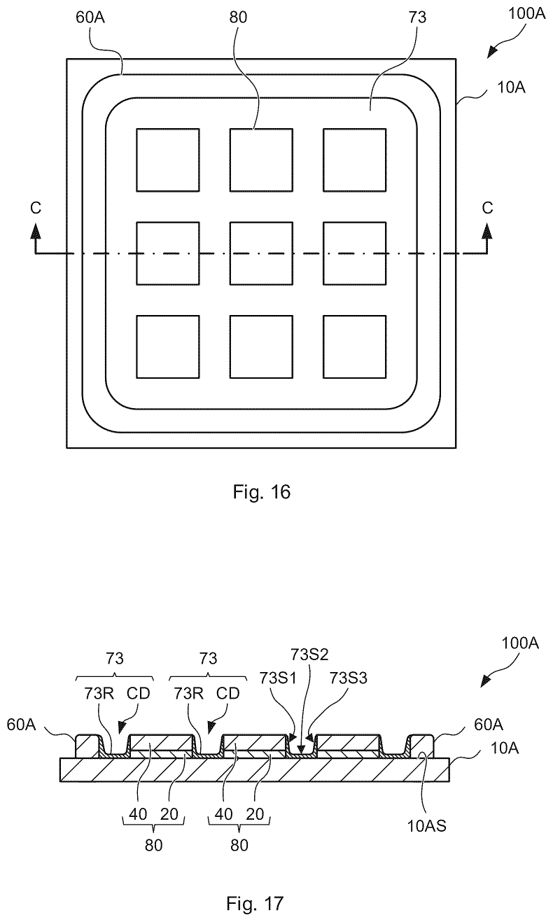

Next, the light-emitting device 100A of Example 2 will be described. FIG. 16 is a top view of a light-emitting device 100A according to Example 2. FIG. 17 is a cross-sectional view taken along a line C-C of the light-emitting device 100A shown in FIG. 16.

In the light-emitting device 100A, a plurality of light-emitting elements 20 and wavelength converters 40 are arranged on an upper surface 10AS of a substrate 10A. In any configuration except for a frame body 60A of the light-emitting device 100A, the same configuration as that of Example 1 is used. Also in the frame body 60A, a raw material thereof is the same as that of the frame body 60 of Example 1.

In FIG. 16, a first electrode 15 and a second electrode 17 of the substrate 10A, a semiconductor structure layer 23, a cathode electrode 25, and an anode electrode 27 of a light-emitting element 20, an element bonding layer 30, and an adhesive layer 50 are not illustrated.

In Example 2, the light-emitting element 20 and the wavelength converter 40 are described as a light-emitting element structure 80, which is a pair of one light-emitting element 20 and one wavelength converter 40 disposed on an upper surface of the one light-emitting element 20 via the adhesive layer 50.

On the upper surface 10AS of the substrate 10A, a plurality of light-emitting element structures 80 are each arranged in an array at predetermined intervals. On the upper surface 10AS of the substrate 10A, the annular frame body 60A that collectively surrounds the plurality of light-emitting element structures 80 arranged in an array is formed.

The first electrode 15 and the second electrode 17, which are not illustrated, are formed on the substrate 10A, and a wiring pattern is formed between a first mounting electrode 15B and a second mounting electrode 17B such that the plurality of light-emitting element structures 80 are connected to one another in series or in parallel. The substrate 10A may be a single-layer substrate having an loading electrode formed on the upper surface 10AS, a mounting electrode formed on a lower surface, and a through electrode that connects the loading electrode with the mounting electrode, or may be a multi-layer substrate with an intermediate wiring layer formed.

A light scattering part 73 is formed between the respective light-emitting element structures 80 adjacent to one another. The light scattering part 73 is formed of: a light scattering material 73R that integrally covers a surface from an upper end of a side surface of one light-emitting element structure 80 of the plurality of light-emitting element structures 80 to an upper end of a side surface of another light-emitting element structure 80 disposed adjacent to the one light-emitting element structure 80, and has an opening at the top; and a recessed space CD that is surrounded by the surface of the light scattering material 73R and opened upward. That is, the light scattering material 73R is formed so as to have a surface shape similar to that of the light scattering material 70R of Example 1, from the upper end of the side surface of one light-emitting element structure 80 to the upper end of the side surface of another light-emitting element structure 80 disposed adjacent to the one light-emitting element structure 80.

Accordingly, the light scattering material 73R has a first inclined surface 73S1 that is inclined outwardly downward from the upper end of the side surface of one light-emitting element structure 80. The light scattering material 73R has a flat surface 73S2 formed continuously with the first inclined surface 73S1 and extending along the upper surface 10AS of the substrate 10A. The light scattering material 73R has a second inclined surface 7383 formed continuously with an outer end of the flat surface 73S2 and inclined upward toward an upper end of the side surface of another light-emitting element structure 80 opposed to the side surface of the one light-emitting element structure 80, that is, inclined outwardly upward.

Between the respective light-emitting element structures 80 adjacent to one another, an inclined surface of the light scattering material 73R formed between the respective side surfaces of the light-emitting element structures 80 adjacent to one another may be both of the first inclined surface 73S1 and the second inclined surface 73S3.

In the light-emitting device 100A of Example 2, the light scattering material 73R having a shape similar to that of the light scattering material 70R of Example 1 is formed between the respective light-emitting element structures 80 adjacent to one another and between the light-emitting element structure 80 and the frame body 60A.

Therefore, the light-emitting device 100A of Example 2 can achieve the same effects as those of the light-emitting device 100 of Example 1, and can avoid a decrease in total luminous flux of light emitted from the light-emitting device 100A and increase a light extraction efficiency.

That is, in the light-emitting device 100A of Example 2, the light emitted from the side surface of the light-emitting element 20 and the light emitted from the side surface of the wavelength converter 40 reach a first inclined surface 73S1 while being scattered inside the light scattering material 73R, are emitted from the first inclined surface 73S1 into the space CD, and are emitted upward from an opening of the light scattering material 70R.

The light-emitting device 100A of Example 2 can be manufactured by a manufacturing method similar to that of the light-emitting device 100 of Example 1. The method for manufacturing the light-emitting device 100A will be described in terms of differences from the light-emitting device 100 of Example 1.

As shown in FIG. 16, the plurality of light-emitting element structures 80 are arranged in an array on the upper surface 10AS of the substrate 10A (Steps S12 and S13 of FIG. 5, the element bonding step and the wavelength converter bonding step).

Next, the frame body 60A is formed on the upper surface 10AS of the substrate 10A so as to collectively surround the plurality of light-emitting element structures 80 arranged in an array (Step S14 of FIG. 5, the frame body forming step). In this step, first, a dispenser filled with a raw material resin of the frame body 60A is used to draw with the raw material resin of the frame body 60A so as to collectively surround the plurality of light-emitting element structures 80. Then, the substrate 10A in this state is heated to form the frame body 60A.

Next. a raw material resin of the light scattering material 73R is applied between the respective plurality of light-emitting element structures 80 and between the light-emitting element structure 80 and the frame body 60A (Step S15 of FIG. 5, the light scattering resin application step). In this step, a dispenser filled with the raw material resin of the light scattering material 73R is used to apply the raw material resin of the light scattering material 73R between the respective plurality of light-emitting element structures 80 and between the light-emitting element structure 80 and the frame body 60A.

Next, as shown in FIG. 17, the raw material resin of the light scattering material 73R is cured by heating the substrate 10A with the raw material resin of the light scattering material 73R applied (Step S16 of FIG. 5, the light scattering resin curing step). In this step, the raw material resin of the light scattering material 73R is continuously heated to a predetermined temperature in one step, thereby forming a light scattering material 73R having the first inclined surface 73S1, the flat surface 73S2, and the second inclined surface 73S3, and the recessed space CD surrounded by each of the surfaces and opened upward, between the respective adjacent light-emitting element structures 80 and between the light-emitting element structure 80 and the frame body 60A.

As described above, the light-emitting device 100A of Example 2 can be manufactured with the manufacturing method similar to that of the light-emitting device 100 of Example 1.

### Example 3

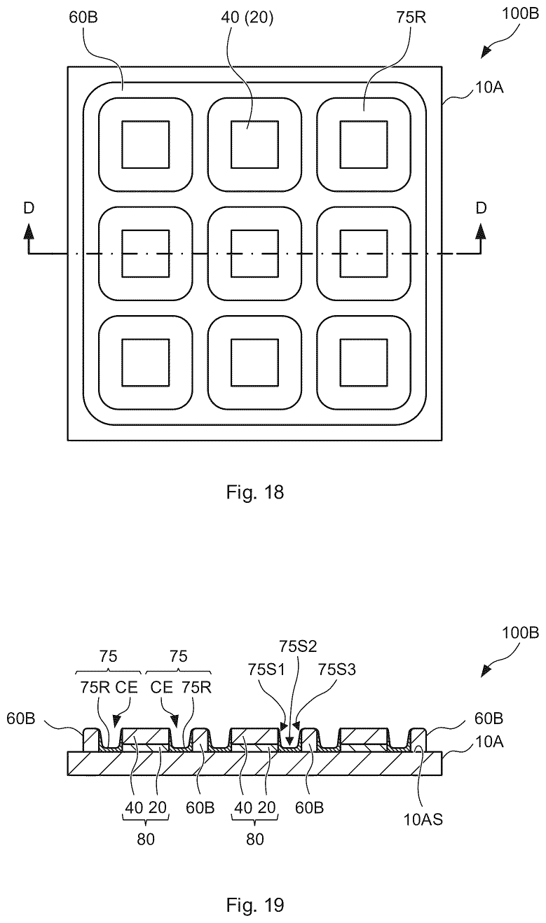

Next, a light-emitting device 100B of Example 3 will be described. FIG. 18 is a top view of the light-emitting device 100B according to Example 3. FIG. 19 is a cross-sectional view taken along a line D-D of the light-emitting device 100B shown in FIG. 18.

The light-emitting device 100B basically has a configuration similar to that of the light-emitting device 100A of Example 2. In the light-emitting device 100B of Example 3, a frame body 60B is formed in a lattice shape so as to surround each of the plurality of light-emitting element structures 80 arranged in an array on the substrate 10A.

In any configuration except for the frame body 60B of the light-emitting device 100B, the same configuration as that of Example 1 is used. Also in the frame body 60B, a raw material thereof is the same as those of the frame body 60 of Example 1 and the frame body 60A of Example 2.

On the upper surface 10AS of the substrate 10A, the plurality of light-emitting element structures 80 are each arranged in an array at predetermined intervals. On the upper surface 10AS of the substrate 10A, the frame body 60B is formed in a lattice shape, which is integrally formed so as to separately surround each of the plurality of light-emitting element structures 80 arranged in an array. In other words, the frame body 60B has a structure shared by the adjacent light-emitting element structures 80.

Thus, by individually surrounding the light-emitting element structure 80 with the frame body 60, a phenomenon in which an emitted light extends to a unit of the adjacent light-emitting element structures 80 surrounded by the frame body 60B can be suppressed when the separate light-emitting element structures 80 are individually lit (suppression of a crosstalk phenomenon).

A light scattering part 75 is formed between the respective light-emitting element structures 80 and the frame body 60B. The light scattering part 75 is formed of: a light scattering material 75R that integrally covers a surface from an upper end of a side surface of one light-emitting element structure 80 to an upper end of an inner surface of the frame body 60B surrounding the one light-emitting element structure 80, and has an opening at the top; and a recessed space CE that is surrounded by the light scattering material 75R and opened upward.

Accordingly, the light scattering material 75R has a first inclined surface 75S1 that is inclined outwardly downward from the upper end of the side surface of each of the light-emitting element structures 80. The light scattering material 75R has a flat surface 75S2 formed continuously with the first inclined surface 75S1 and extending along the upper surface 10AS of the substrate 10A. The light scattering material 75R has a second inclined surface 75S3 that is formed continuously with the outer end of the flat surface 75S2 and is inclined toward the upper end of the inner surface of the frame body 60B surrounding the one light-emitting element structure 80, that is, inclined outwardly upward.

That is, the light scattering material 75R is formed so as to have a surface shape similar to that of the light scattering material 70R of Example 1, from the upper end of the side surface of one light-emitting element structure 80 to the upper end of the inner surface of the frame body 60B surrounding the one light-emitting element structure 80. In other words, in the light-emitting device 100B, a plurality of sets of the light-emitting element structure 80 including the light-emitting element 20 and the wavelength converter 40, the light scattering part 75, and the frame body 60B are arranged in an array on the upper surface 10AS of the substrate 10A.

Therefore, the light-emitting device 100B of Example 3 can achieve the same effects as those of the light-emitting device 100 of Example 1, and can avoid a decrease in total luminous flux of light emitted from the light-emitting device 100B and increase the light extraction efficiency.

That is, in the light-emitting device 100B of Example 3, the light emitted from the side surface of the light-emitting element 20 and the light emitted from the side surface of the wavelength converter 40 reach a first inclined surface 70S1 while being scattered inside the light scattering material 75R, are emitted from the first inclined surface 75S1 into the space CD, and are emitted upward from an opening of the light scattering material 70R.

The light-emitting device 100B of Example 3 can be manufactured by a manufacturing method similar to that of the light-emitting device 100A of Example 2. The method for manufacturing the light-emitting device 100B will be described in terms of differences from the light-emitting device 100A of Example 2.

As shown in FIG. 18, on the upper surface 10AS of the substrate 10A, the frame body 60B is formed in a lattice pattern around the plurality of light-emitting element structures 80 arranged in an array and between the respective plurality of light-emitting element structures 80 (Step S14 of FIG. 5, the frame body forming step). In this step, first, the dispenser filled with the raw material resin of the frame body 60B is used to draw with the raw material resin of the frame body 60B in a lattice shape around the plurality of light-emitting element structures 80 arranged in an array and between the respective plurality of light-emitting element structures 80. Then, the substrate 10A in this state is heated to form the frame body 60B.

Next, a raw material resin of the light scattering material 75R is applied between each of the light-emitting element structures 80 and the frame body 60B (Step S15 of FIG. 5, the light scattering resin application step). In this step, a dispenser filled with the raw material resin of the light scattering material 75R is used to apply the raw material resin of the light scattering material 75R between each of the light-emitting element structures 80 and the frame body 60B.

Next, as shown in FIG. 19, the raw material resin of the light scattering material 75R is cured by heating the substrate 10A with the raw material resin of the light scattering material 75R applied (Step S16 of FIG. 5, the light scattering resin curing step). In this step, the raw material resin of the light scattering material 75R is continuously heated to a predetermined temperature in one step, thereby forming the light scattering part 75 having the first inclined surface 75S1, the flat surface 75S2, and the second inclined surface 75S3, and the recessed space CE surrounded by each of the surfaces and opened upward, between each of the light-emitting element structures 80 and the frame body 60B.

As described above, the light-emitting device 100B of Example 3 can be manufactured with the manufacturing method similar to that of the light-emitting device 100A of Example 2.

While the examples of the present invention have been described above, these are merely presented as examples, and the invention is not limited to the examples.

For example, in Example 1, the frame body 60 has the inner surface extending in a direction perpendicular to the upper surface 10S of the substrate 10 in each of the drawings. However, for example, the inner surface of the frame body 60 may be formed to be inclined inward from the upper end. By inclining the inner surface of the frame body 60, an inclination angle of the second inclined surface 70S3 of the light-emitting device 100 of Example 1 can be adjusted, enabling a light distribution property of the light-exiting surface of the light-emitting device 100 to be adjusted. The adjustment of the light distribution property is also applicable to Examples 2 and 3.

### Modification

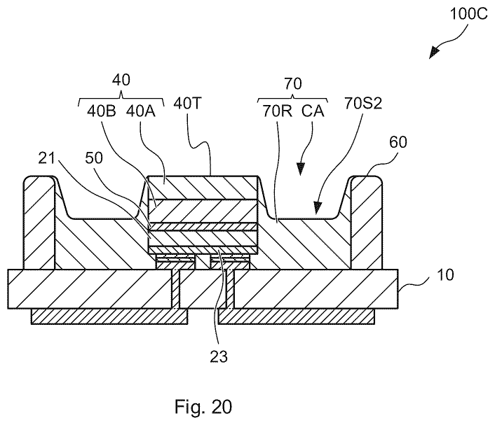

FIG. 20 is a cross-sectional view of a light-emitting device 100C according to Modification.

As shown in FIG. 20, in the light-emitting device 100C, the wavelength converter 40 may be configured by an upper layer 40A that has a light scattering property and contains a phosphor (light converter) and a non-scattering and translucent lower layer 40B. Such a structure increases a light guide thickness of the light LM1 and the light LM2, increases the light LM6 emitted from the space CA, and allows the light LMS emitted from the upper surface 40T of the wavelength converter 40 to be reduced. In this case, a lower surface end of the wavelength converter 40 is a boundary surface between the upper layer 40A and the lower layer 40B. The growth substrate 21 includes a translucent lower layer portion. In other words, in this case, it is sufficient that a height of the flat surface 70S2 of the light scattering part 70 is lower than a lower surface of the upper layer 40A. This two-layer structured wavelength converter 40 can be formed by forming two layers of the upper layer 40A and the lower layer 40B or by bonding the upper layer 40A and the lower layer 40B.

Thus, the described examples are not intended to limit the scope of the invention. The described examples can be performed in other various forms, and various kinds of omissions, replacements, and changes are allowed without departing from the gist of the invention. Those modifications are also included within the scope and the gist of the invention, and are included in the scope of the invention described in the claims and the equivalents thereof.

### DESCRIPTION OF REFERENCE SIGNS

100 light-emitting device
10 substrate
15 first electrode
17 second electrode
20 light-emitting element
21 growth substrate
23 semiconductor structure layer
25 cathode electrode
27 anode electrode
30 element bonding layer
40 wavelength converter
50 adhesive layer
60 frame body
70, 73, 75 light scattering part

1. A light-emitting device comprising:
a plate-shaped substrate;
a light-emitting element including a semiconductor structure layer and a translucent substrate, the semiconductor structure layer being disposed on one main surface of the substrate and including a light-emitting layer, the translucent substrate being disposed on the semiconductor structure layer and having a plate shape and a translucency;
a wavelength converter containing phosphor particles and disposed on an upper surface of the translucent substrate via an adhesive resin; and
a light scattering material made of a resin material containing light scattering particles, the light scattering material being formed so as to cover from a side surface of the wavelength converter to a side surface of the light-emitting element and the one main surface of the substrate, wherein
the light scattering material includes:
a first inclined surface inclined outwardly downward from an upper end of the side surface of the wavelength converter;
a flat surface formed continuously with the first inclined surface and extending along the one main surface; and
a second inclined surface formed continuously with an outer end of the flat surface and inclined outwardly upward, and
a height position of the flat surface from the one main surface of the substrate is lower than a lower surface of the wavelength converter.

2. The light-emitting device according to claim 1, wherein the height position of the flat surface from the one main surface of the substrate is at or lower than ½ a thickness of the translucent substrate from the upper surface of the translucent substrate.

3. The light-emitting device according to claim 1, wherein the height position of the flat surface from the one main surface of the substrate is at or lower than ⅓ a thickness of the translucent substrate from the upper surface of the translucent substrate.

4. The light-emitting device according to claim 1, wherein a height position of an upper end of the second inclined surface from the one main surface of the substrate is at a height position equal to or higher than the upper surface of the wavelength converter.

5. The light-emitting device according to claim 1, wherein the wavelength converter is a ceramic fired body containing the phosphor particles.

6. The light-emitting device according to claim 1, wherein the wavelength converter is a light scattering ceramic polycrystal body obtained by mixing and firing the phosphor particles and ceramic particles.

7. The light-emitting device according to claim 1, wherein:
the light scattering particles are made of titanium oxide, and
the light scattering material is made of a translucent resin in which the light scattering particles are dispersed at a content rate of 8 to 30 wt %.

8. The light-emitting device according to claim 1, further comprising:
a frame body formed in contact with an outer side of the light scattering material on the one main surface of the substrate.

9. The light-emitting device according to claim 8, wherein a height position of an upper end of the frame body from the one main surface of the substrate is at a height position equal to or higher than the upper surface of the wavelength converter.

10. The light-emitting device according to claim 8, wherein a plurality of sets of the light-emitting element, the wavelength converter, the light scattering material, and the frame body are arranged in an array on the one main surface of the substrate.

11. The light-emitting device according to claim 1, further comprising:
a pair of electrodes on a lower surface of the semiconductor structure layer; and
a conductive light reflection layer between the semiconductor structure layer and the pair of electrodes.

12. A light-emitting device comprising:
a substrate structure including a plate-shaped portion having a plate shape and a wall portion formed in a frame shape on one main surface of the plate-shaped portion;
a light-emitting element including a semiconductor structure layer and a translucent substrate, the semiconductor structure layer being disposed on the one main surface in the wall portion and including a light-emitting layer, the translucent substrate being disposed on the semiconductor structure layer and having a plate shape and a translucency;
a wavelength converter containing phosphor particles and disposed on an upper surface of the translucent substrate via an adhesive resin; and
a light scattering material made of a resin material containing light scattering particles, the light scattering material being formed so as to cover a side surface of the wavelength converter, a side surface of the light-emitting element, and the one main surface of the plate-shaped portion and an inner surface of the wall portion, wherein
the light scattering material includes:
a first inclined surface inclined outwardly downward from an upper end of the side surface of the wavelength converter;
a flat surface formed continuously with the first inclined surface and extending along the one main surface; and
a second inclined surface formed continuously with an outer end of the flat surface and inclined upward toward an upper end of the inner surface of the wall portion, and
a height position of the flat surface from the one main surface of the plate-shaped portion is lower than a lower surface of the wavelength converter.

13. A light-emitting device comprising:
a plate-shaped substrate;
a plurality of light-emitting element structures each including a semiconductor structure layer, a translucent substrate, and a wavelength converter, the semiconductor structure layer being disposed on one main surface of the substrate and including a light-emitting layer, the translucent substrate being disposed on the semiconductor structure layer and having a plate shape and a translucency, the wavelength converter containing phosphor particles and each being disposed on an upper surface of the translucent substrate via an adhesive resin, the plurality of light-emitting element structures being arranged in an array on the one main surface; and
a light scattering material made of a resin material containing light scattering particles, the light scattering material being formed so as to cover from a side surface of one light-emitting element structure of the plurality of light-emitting element structures to a side surface of another light-emitting element structure disposed adjacent to the one light-emitting element structure, wherein
the light scattering material includes:
a first inclined surface inclined outwardly downward from an upper end of the side surface of the one light-emitting element structure;
a flat surface formed continuously with the first inclined surface and extending along the one main surface; and
a second inclined surface formed continuously with an outer end of the flat surface and inclined upward toward an upper end of a side surface of the other light-emitting element structure opposed to the side surface of the one light-emitting element structure, and
a height position of the flat surface from the one main surface of the substrate is at a position lower than a lower surface of the wavelength converter.

14. A method for manufacturing a light-emitting device, comprising:
a step of preparing a plate-shaped substrate;
an element bonding step of bonding a light-emitting element onto one main surface of the substrate, the light-emitting element including a semiconductor structure layer and a translucent substrate, the semiconductor structure layer including a light-emitting layer, the translucent substrate being disposed on the semiconductor structure layer and having a plate shape and a translucency;
a wavelength converter bonding step of bonding a wavelength converter containing phosphor particles to an upper surface of the translucent substrate via an adhesive resin;
a light scattering resin application step of applying a thermosetting light scattering resin containing light scattering particles onto the one main surface of the substrate; and
a resin curing step of heating the light scattering resin to form a light scattering material that covers from a side surface of the wavelength converter to a side surface of the light-emitting element and the one main surface of the substrate, wherein
in the resin curing step,
the light scattering resin is continuously heated to a predetermined temperature in one step to form the light scattering material in which a first inclined surface inclined outwardly downward from an upper end of the side surface of the wavelength converter, a flat surface formed continuously with the first inclined surface and extending along the one main surface, and a second inclined surface formed continuously with an outer end of the flat surface and inclined outwardly upward are integrally formed, and
the flat surface is formed such that a height position of the flat surface from the one main surface of the substrate is lower than a lower surface of the wavelength converter.
